(19) United States
(12) Patent Application Publication
(10) Pub. No.: US 2026/0042184 A1
(43) Pub. Date: Feb. 12, 2026

(54) CONTROL OF PLATEN EDGE-SHAPE IN CHEMICAL MECHANICAL POLISHING

(71) Applicant: Applied Materials, Inc., Santa Clara, CA (US)

(72) Inventors: Steven M. Zuniga, Soquel, CA (US); Jay Gurusamy, Santa Clara, CA (US); Jeonghoon Oh, Saratoga, CA (US)

(21) Appl. No.: 18/799,562

(22) Filed: Aug. 9, 2024

(51) Int. Cl. B24B 37/10; B24B 37/04; H01L 21/306

(52) U.S. Cl. CPC B24B 37/105; B24B 37/042; H01L 21/30625

(57) ABSTRACT

Disclosed herein is a chemical mechanical polishing apparatus, including a platen having an upper surface to support a polishing pad, the platen having an annular chamber below and separated from a portion of an upper surface of the platen by a plate that is sufficiently flexible to deflect under a change of a pressure in the annular chamber, the platen having a channel fluidically connecting the annular chamber to a port in the platen; a pressure source coupled to the port to control the pressure in the annular chamber; a carrier head to hold a surface of a substrate against the polishing pad; and a motor to generate relative motion between the platen and the carrier head so as to polish an overlying layer on the substrate.

### TECHNICAL FIELD

The disclosure relates to chemical mechanical polishing, and more specifically to controlling platen shape in chemical mechanical polishing.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of a patterned layer is exposed. A conductive filler layer, for example, can be deposited on a patterned insulative layer to fill the trenches or holes in the insulative layer. After planarization, the portions of the metallic layer remaining between the raised pattern of the insulative layer form vias, plugs, and lines that provide conductive paths between thin film circuits on the substrate. For other applications, such as oxide polishing, the filler layer is planarized, e.g., by polishing for a predetermined time period, to leave a portion of the filler layer over the nonplanar surface. In addition, planarization of the substrate surface is usually required for photolithography.

One problem in CMP is variations in the material removal rate, and subsequent thickness profile, of the substrate. Variations in the slurry distribution, polishing pad condition, the relative speed between the polishing pad and the substrate, and the inconsistent load on the substrate from the pressurized chambers of the carrier head can cause variations in the material removal rate. These variations, as well as variations in the initial thickness of the substrate layer, cause variations final substrate layer thickness, particularly in edge regions.

### SUMMARY

Disclosed herein is a chemical mechanical polishing apparatus including one or more annular chambers in a platen supporting a polishing pad. A fluid pressure within each annular chamber is controlled to flex, e.g., vertically bias, a region of the platen above the corresponding chamber which biases a corresponding region of the pad supported on the platen. The carrier head moves a portion of the substrate over the biased region to locally increase or decrease the polishing rate, which can reduce the presence of polishing non-uniformities in the polishing substrate. A controller of the apparatus commands the displacement associated with the regions of the annular chambers by controlling the pressures with a fluid pump.

The apparatus includes an in-situ monitoring system, such as an optical monitoring system, which receives a signal indicative of a radial thickness profile of an overlying layer of material on the substrate. The controller processes the signal and determines whether additional polishing is needed in an annular region of the substrate, for example an annular region at the edge of the substrate. When additional polishing is needed, the controller causes a fluid pressure in the annular chambers to increase which causes the platen and pad region to flex upward, whereas when less polishing is needed the controller causes the actuators to flex the platen and pad region downward. The carrier head moves a portion of the substrate over the flexed region for additional polishing.

The carrier head moves the substrate off of the flexed annular region and the thickness profile is re-determined. If the thickness profile is within a uniformity threshold, additional polishing (if needed) can be performed without using the annular chamber region. If the thickness profile does not meet the uniformity threshold, the controller determines that additional polishing over the annular chamber is needed.

In general, an aspect disclosed herein is a chemical mechanical polishing apparatus, the chemical mechanical polishing apparatus having a platen having an upper surface to support a polishing pad, the platen having an annular chamber below and separated from a portion of an upper surface of the platen by a plate that is sufficiently flexible to deflect under a change of a pressure in the annular chamber, the platen having a channel fluidically connecting the annular chamber to a port in the platen; a pressure source coupled to the port to control the pressure in the annular chamber; a carrier head to hold a surface of a substrate against the polishing pad; and a motor to generate relative motion between the platen and the carrier head so as to polish an overlying layer on the substrate.

Examples may include one or more of the following features. The annular chamber can have a radial width of up to 2 inches. The plate may include a ring secured over a recess in the platen to form the chamber. The plate can be a disk-shaped cover covering an entirety of the platen including over a recess to form the chamber. The plate can be a unitary body with a surrounding portion of the platen. The plate can be a metal material or polymer material. The plate can be aluminum having a thickness of up to 0.030 inches. The plate can be polyether ether ketone (PEEK) or polyphenylene sulfide (PPS) having a thickness of up to 0.080 inches. A floor of the annular chamber can be sealed with a flexure. The flexure can be affixed to the platen by an annular clamp. The apparatus may include an annular gasket between the clamp and the platen. The annular clamp may include a first clamp holding the flexure to an outer edge of the platen and a second clamp holding an opposing edge of the flexure to an inner portion of the platen. The apparatus may include a second annular chamber separated vertically from the annular chamber, the second annular chamber beneath a second portion of the upper surface of the platen, and the portion and the second portion are partially overlapping. The second annular chamber can be arranged at a different radial distance to a center of the platen than the annular chamber. The second annular chamber can be sealed with a second clamp. The annular chamber may include no more than an outermost 25% by radius of the platen.

In general, an aspect disclosed herein is a method of locally polishing a substrate. The method includes supporting a polishing pad with a rotatable platen, the platen including an annular chamber below and separated from a portion of an upper surface of the platen; pressurizing the chamber to adjust a vertical height of the portion of the upper surface relative to a central region along an entire circumference of the annular chamber; positioning the substrate so that a portion of the substrate is over the annular chamber; and generating relative motion between the polishing pad and a substrate so as to polish an overlying layer on the substrate.

Examples may include one or more of the following features. The method may include determining a thickness profile of the overlying layer; determining, from the thickness profile, to provide differential polishing to an annular region of the substrate; adjusting the height of the portion of the upper surface relative to the central region to provide the differential polishing to an annular region of the substrate. The method may include continuing the relative motion between the polishing pad and the substrate until the region of the substrate can be within a uniformity threshold of the remaining substrate.

Particular implementations of the subject matter described in this specification can be implemented so as to realize one or more of the following technical advantages.

Radially-specific thickness profile correction can be performed, and within-wafer non-uniformity and wafer-to-wafer non-uniformity can be reduced. Material removal can compensate for thickness profile non-uniformities in edge regions induced following a main polishing step or to correct incoming substrate film thickness profiles before undergoing primary polishing. The amount of flex (e.g., displacement from a planar configuration) by the annular chamber results in a modification of pressure applied to the substrate surface rather than through the substrate backside, increasing the polishing location specificity during location-specific polishing. The dimensions of the region of increased pressure can be small compared to the overall substrate surface area and can be controlled by positioning of the substrate with the carrier head, allowing material removal in highly specific areas.

The details of one or more embodiments are set forth in the accompanying drawings and the description below. Other aspects, features and advantages will be apparent from the description and drawings, and from the claims.

### DESCRIPTION OF DRAWINGS

FIG. 1A illustrates a schematic cross-sectional view of an example of a polishing apparatus having an annular chamber for controlling an edge-shape of a platen.

FIGS. 1B and 1C illustrate a schematic cross-sectional view of a portion of a platen that includes the annular chamber.

FIGS. 1D and 1E illustrate top views of exemplary platens for the apparatus of FIG. 1A.

FIG. 2A illustrates a schematic cross-sectional view of another implementation of the annular chamber.

FIG. 2B illustrates a schematic cross-sectional view of still another implementation of the annular chamber.

FIG. 3 illustrates a schematic cross-sectional view of an annular chamber sealed with a clamp.

FIG. 4A illustrates a schematic cross-sectional view of an annular chamber sealed with a flexure.

FIG. 4B illustrates a top view of a platen of the apparatus of FIG. 4A.

FIG. 5A illustrates a schematic cross-sectional view of an example platen having two annular chambers.

FIG. 5B illustrates a top view of a platen of the apparatus of FIG. 5A.

FIG. 6 is a flow chart diagram illustrating a method of polishing an annular region of a substrate.

In the figures, like references indicate like elements.

### DETAILED DESCRIPTION

In some chemical mechanical polishing operations, a portion of a substrate can be under-polished or over-polished. In particular, the substrate tends to be over-polished or under-polished at or near the substrate edge. One technique to address such polishing non-uniformity is to have multiple controllable pressurizable annular chambers in the carrier head. However, pressure applied from the backside of the substrate tends to “spread,” such that compensation for radially localized non-uniformity can be difficult. Another technique is to transfer the substrate to a separate “touch up” tool, e.g., to perform edge-correction. However, the additional tool consumes valuable footprint within the clean room and can have an adverse effect on throughput.

An alternative approach is to have a platen with one or more pressurizable chambers, which when over-or under-pressurized, produce a deflection, e.g., upwardly or downwardly, in a portion of an upper surface of the platen. A portion of the substrate, e.g., an annular portion, is then moved over the deflected portion of the upper surface, which results in increased or decreased pressure between a polishing pad supported by the platen and the substrate at that portion, thus enabling radially-targeted polishing of an edge portion of the substrate. Having the annular chamber enclosed by a portion of the platen can be superior to simply having the polishing pad cover a recess in the top surface of the platen because the region of the polishing pad can be actively controlled through pressure in the annular chamber. In addition, attachment of the pad to the platen can be easier and delamination of the pad can be less likely with the creased contact area provided by an annular chamber enclosed by a portion of the platen. In addition, as compared to having individually vertically movable sections of the platen, a platen with a deflectable surface can present lower risk of damage to the substrate.

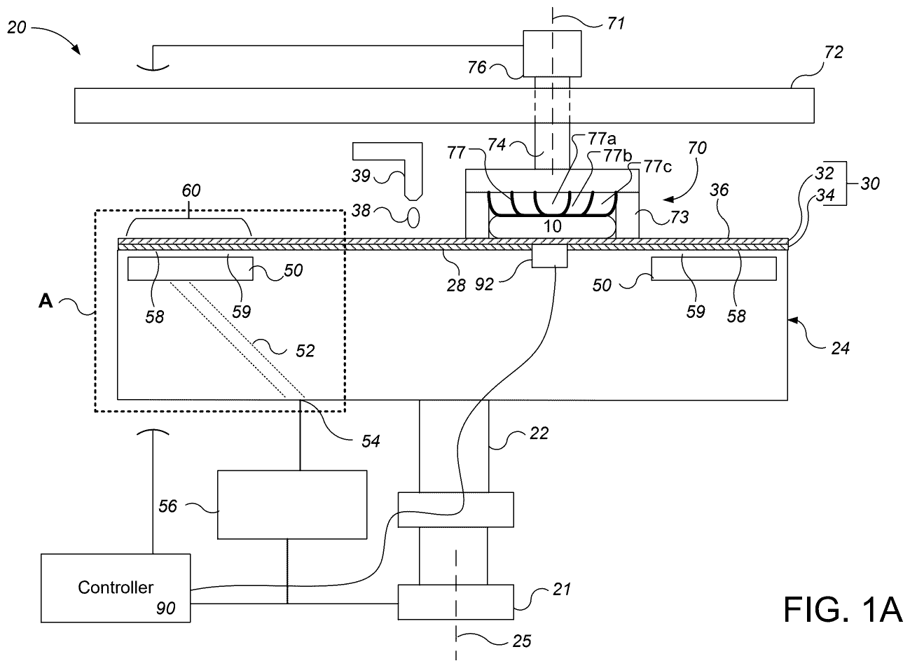

FIG. 1A shows a polishing system 20 operable to polish a substrate 10. The polishing system 20 includes a rotatable platen 24 on which a polishing pad 30 is situated. The platen 24 is operable to rotate about an axis of rotation 25. For example, a motor 21 can turn a drive shaft 22 to rotate the platen 24. An upper surface 28 of the platen 24 supports the polishing pad 30.

The polishing pad 30 can be secured to the upper surface 28 of the platen 24, for example, by a layer of adhesive. When worn, the polishing pad 30 can be detached and replaced. The polishing pad 30 can be a two-layer polishing pad with an outer polishing layer 32 having a polishing surface 36 and a softer backing layer 34.

The polishing system 20 can include a polishing liquid delivery arm 39 and/or a pad cleaning system such as a rinse fluid delivery arm. During polishing, the arm 39 is operable to dispense a polishing liquid 38, e.g., slurry with abrasive particles. In some implementations, the polishing system 20 include a combined slurry/rinse arm. Alternatively, the polishing system can include a port in the platen operable to dispense the polishing liquid 38 onto the polishing pad 30.

The polishing system 20 includes a carrier head 70 operable to hold the substrate 10 against the polishing pad 30. The carrier head 70 is suspended from a support structure 72, for example, a carousel or track, and is connected by a carrier drive shaft 74 to a carrier head rotation motor 76 so that the carrier head can rotate about an axis 71. In addition, the carrier head 70 can oscillate laterally across the polishing pad 30, e.g., by moving in a radial slot in the carousel as driven by an actuator, by rotation of the support structure 72 as driven by a motor, or movement back and forth along the support structure 72 as driven by an actuator. In operation, the platen 24 is rotated about its central axis of rotation 25, and the carrier head 70 is rotated about its central axis 71 and translated laterally across the polishing surface 36 of the polishing pad 30.

The carrier head 70 can include a retaining ring 73 to retain the substrate 10 below a flexible membrane 77. The carrier head 70 also includes one or more independently controllable pressurizable chambers defined by the membrane, e.g., three chambers 77a-77c, which can apply independently controllable pressurizes to associated zones on the flexible membrane 77 and thus on the substrate 10. Although only three chambers are illustrated in FIG. 1 for ease of illustration, there could be one or two chambers, or four or more chambers, e.g., five chambers.

A controller 90, such as a programmable computer, is connected to the platen motor 21 and the carrier head motor 76 to control the rotation rate of the platen 24 and carrier head 70. For example, the platen motor 21 and the carrier head motor 76 can include an encoder that measures the rotation rate of the associated drive shaft.

In the example of FIG. 1A, the polishing system 20 includes at least one annular chamber 50 that extends radially from the rotational axis 25 of the platen 24. Generally but without expressing limitation, the annular chamber 50 extends circumferentially around the platen 24. The annular chamber 50 can extend circumferentially around the entire platen 24, or partially along an arc section of the platen 24. The annular chamber 50 extending along an arc section can enable asymmetry control by synchronizing platen 24 rotation with motion of the carrier head 70 to polish a specific area of the substrate 10. The ceiling of the chamber 50 formed by a plate 59 of material that is more rigid than the polishing pad 30 and the flexible membrane 77 in the carrier head 70. As such, the chamber 50 can be considered to be enclosed within the platen 24. The annular chamber 50 can be a continuous annular volume extending circumferentially of the platen 24. A continuous chamber 50 is pressurizable by a single port and pressure source.

The plate 59 can be a metal, e.g., the same metal as the remainder of the platen 24. The plate can have a flexural modulus of 100 to 16000 kpsi, e.g., 200 to 12000 kpsi.

If not deflected, an upper surface 58 of the plate 59 is substantially coplanar with the remaining upper surface 28 of the platen 24. A channel 52 fluidically connects the chamber 50 to an opening 54 in the platen 24. A pressure source 56 is connected to the opening 54 in order to change a pressure within the chamber 50. The pressure source 56 functions to raise, lower, or maintain a fluid (e.g., a gas, or a liquid) pressure in the chamber 50 according to instructions received from the controller 90. In some examples, the pressure source 56 uses air, or water, to control the pressure within the chamber 50.

Referring to FIGS. 1B and 1C, a cross-sectional view of window A of FIG. 1A is shown which illustrates the chamber 50 within the platen 24. The dimensions and positioning of the chamber 50 are illustrative and not limiting. When the pressure source 56 raises the pressure within the chamber 50 above a set point, such as standard atmospheric pressure, the chamber 50 expands such that the plate 59 and a portion of the pad 30 above the chamber 50 is urged upward, defining a flexed region 60. Pressure against a region of the substrate 10 increases if the region is present over the flexed region 60. The arrangement and size of the chamber 50 defines the region 60 in which the pressure between the pad 30 and substrate 10 is controlled at least in part by the amount of flexing in the upper surface 58 induced by the pressure in the chamber 50.

Conversely, when the pressure source 56 reduces the pressure within the chamber 50 below the set point, the chamber 50 contracts such that the plate 59 and the upper surface 58 flexes downward and the region 60 of the polishing pad 30 is urged downward. Pressure against a region of the substrate 10 decreases if the region is present over the flexed region 60. In other drawings, the relative upward and downward flex of the pad 30 is illustratively shown in FIG. 1B.

As used herein, the terms “upward” and “downward” are in reference to the orientation of FIG. 1A. Upward refers to the direction from the platen 24 to the polishing pad 30 to the substrate 10, while downward refers to the reverse; in operation the polishing surface could be oriented vertically or some other orientation with respect to gravity.

As used herein, a ‘width’ refers to a radial dimension according to the cylindrically symmetric platen 24 based on a center around the rotational axis 25, e.g., a horizontal dimension in FIG. 1A. Further, a ‘thickness’ refers to a vertical measurement along an axis parallel with the rotational axis 25, e.g., a vertical dimension in FIG. 1.

In some examples, the annular chamber 50 has a width in a range from 1% to 10% of the radius of the platen 24 (e.g., from 2% to 8%, from 3% to 6%, from 5% to 10%, or from 8% to 10%). In one example, the chamber 50 has a width in a range from 0.1″ to 2″, e.g., 1″ or less, 0.5″ or less, or 0.25″ or less. In some examples, the chamber 50 has a thickness in a range from 1% to 10% of the thickness of the platen 24.

Several variables determine the pressure-deflection relationship between the pressure within the chamber 50 and the maximum distance by which the upper surface 58 deflects. Some examples of the pressure-deflection relationship variables include the material from which the plate 59 is constructed, and the thickness of the plate 59. In examples in which the plate 59 is aluminum, the thickness of the plate 59 can be in a range from 0.010″ to 0.030″ (e.g., 0.020″). In examples in which the plate 59 is PEEK or PPS, the thickness can be in a range from 0.030″ to 0.100″ (e.g., 0.050″).

In the examples of FIGS. 1A-1C, the plate 59 is a unitary body with the surrounding platen 24. In one example, the platen 24 can be formed by machining a recess into a bottom surface of a metal disk, leaving the plate 59 connected to the platen 24 by the surrounding side walls of the chamber 50. A metal plate can be secured, e.g., brazed, to the bottom of the disk, enclosing the recess to form the chamber 50. As another example, the chamber 50 can be formed by casting the platen 24 in a mold.

A top-down view of the pad 30 supported by the platen 24 is shown in FIG. 1D and FIG. 1E. FIG. 1D is an example of the platen 24 having a chamber 50 which extends circumferentially around the entire platen 24 to create the flexed region 60. FIG. 1E is an example of the platen 24 having a chamber 50 which extends along an arc of the platen 24 and at a different radial distance from the platen 24 center than the chamber 50 of FIG. 1D, thus a flexed region 61 is created which extends partially around the pad 30. To adjust a polishing rate of a portion 12 of the substrate 10, the substrate 10 is moved by the carrier head 70 such that the portion 12 of the substrate 10 is above the flexed region 60. Depending on whether the chamber 50 is biased upward or downward, the flexed region 60 will experience increased or decreased pressure against the portion 12 of the substrate 10. Due to the rotation (shown by arrow A) of the carrier head 70 and substrate 10, an annular section 12a of the substrate 10 experiences an increased or decreased polishing rate compared to the upper surface 58 remaining in a planar state. While the retaining ring 73 surrounds the substrate 10 in the system 20 during a polishing operation, the component has been visually removed for simplification.

In some implementations, the polishing system 20 includes an in-situ monitoring system. The monitoring system can include a sensor 92 supported on or in the platen. Due to the rotation of the platen, as the sensor travels below the carrier head 70 and the substrate 10, the monitoring system receives measurements at a sampling frequency causing the measurements to be taken at locations in an arc that traverses the substrate 10. From the measurements, the in-situ monitoring system produces a signal which represents the thickness of the layer of material being polished, e.g., a thickness profile. Additionally, or alternatively, the in-situ monitoring system produces a signal which represents the polishing rate of the layer of material being polished, e.g., a polishing rate profile. Conversion of the measurements to the process profile, e.g., the thickness profile or polishing rate profile, can be performed by the controller 90.

The controller 90 can compare the process profile to a target profile. For example, the target profile can be a pre-determined target thickness profile for the radially-dependent thickness of the layer at the end of polishing, or a target polishing rate profile storing radially-dependent target polishing rates during polishing. The process profile can be based on measurements over the radial width of the substrate 10, or a portion of the radial width of the substrate 10. In some implementations, the controller 90 calculates a process profile for the portion of the substrate 10 corresponding to the outermost annular region of the substrate 10, such as the outermost 5%, the outermost 10%, or the outermost 20% of the substrate.

The controller 90 compares the process profile to a target profile. If the process profile differs from the target profile by more than a threshold amount, the controller 90 determines to change a polishing parameter. If the difference occurs in a region of the substrate 10 that is controllable by the flexed region 60, the controller 90 operates the pressure source 56 to change a pressure in the chamber 50 to compensate for the difference of the process profile from the target profile.

If the polishing rate of the portion 12 of the substrate 10 is above a target polishing rate for that portion 12, the controller 90 moves the carrier head 70 and substrate 10 to position the portion 12 over the flexed region 60. The controller 90 controls the pressure source 56 to reduce a fluid pressure in the chamber 50 which flexes the flexed region 60 downward. The downward flex reduces the polishing rate within that region 60 and the portion 12 to achieve the target polishing rate profile.

If the polishing rate of the portion 12 is below the target polishing rate for that portion 12, the controller 90 controls the pressure source 56 to increase a fluid pressure in the chamber 50, which flexes the flexed region 60 upward. The controller 90 moves the carrier head 70 and substrate 10 to position the portion 12 over the flexed region 60 to increase the polishing rate of the portion 12 to achieve the target polishing rate profile.

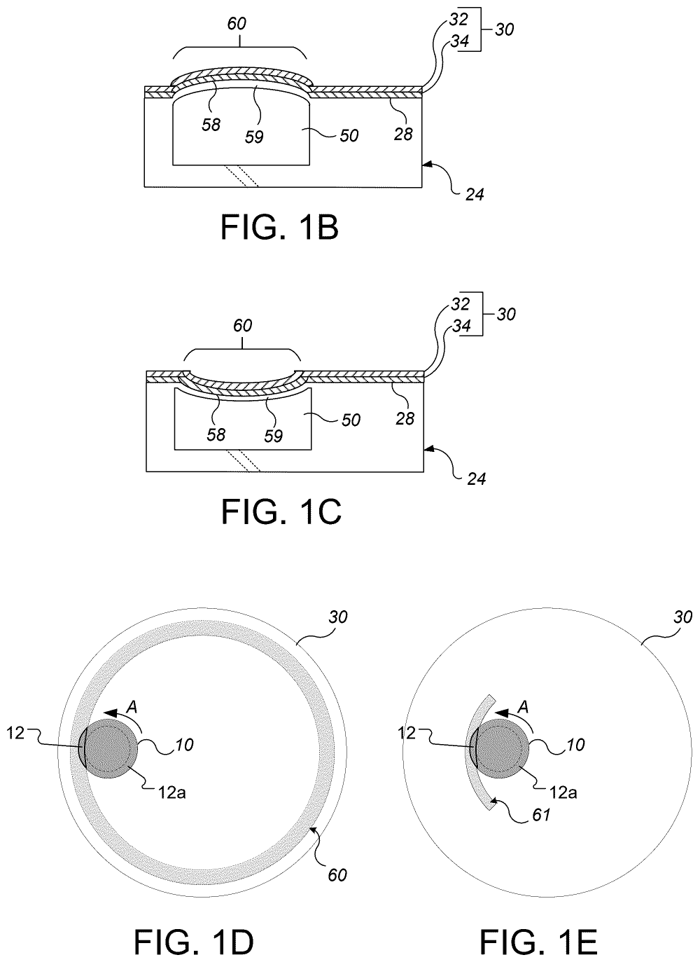

In other examples, the plate 59 is a portion of a component composed of a material that is different than the platen 24. In FIG. 2A, a chamber 50a is formed in a platen 24a by securing an annular ring 62 over a recess in the platen 24a. The ring 62 provides the plate 59 and the deflectable upper surface 58a, and fluidically seals the chamber 50a. The ring 62 can be detachably, or irreversibly, installed on the platen 24a. In one example, the ring 62 extends past the width of the chamber 50a by a distance so that the ring 62 can be installed to the platen 24a by fasteners, e.g., screws, which hold the ring 62 to the platen 24a during a polishing operation.

The ring 62 is constructed from a material which flexes when the pressure of the chamber 50a is changed from the set point, such as aluminum, polyether ether ketone (PEEK), or polyphenylene sulfide (PPS). In examples in which the ring 62 is aluminum, the thickness of the ring 62 is in a range from 0.10″ to 0.050″ (e.g., 0.020″), or has a flexural modulus of 8,000 to 12,000 kpsi (e.g., 10,000 kpsi). In examples in which the ring 62 is PEEK or PPS, the thickness is in a range from 0.020″ to 0.100″ (e.g., 0.050″), or has a flexural modulus of 400 to 1,000 kpsi (e.g., 600 kpsi).

In another example and referring to FIG. 2B, a disk-shaped cover 63 which extends across the entirety of the upper surface 28 is arranged and detachably or irreversibly secured over a recess in the platen 24a to cover and fluidically seal the recess, thereby forming the chamber 50a. The cover 63 being installed on the entire upper surface 28 permits chambers in addition to chamber 50a at different radial locations in the platen 24a (not shown). The cover 63 can provide the plate 29 and can be composed the materials described with respect to the ring 62.

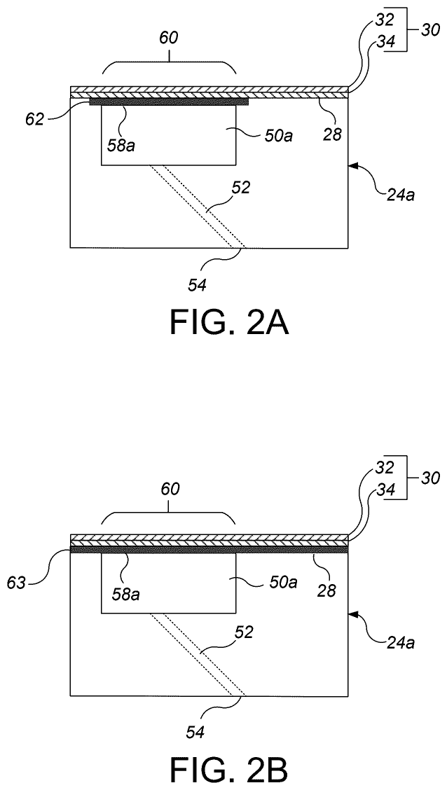

Another example of a platen 24 for edge polishing control is shown in FIG. 3. The platen 24b includes a chamber 50b which extends into the platen 24b from an edge and is sealed by a clamp 68. The interface between the clamp 68 and the platen 24b includes gaskets 80, e.g., gasket 80′ and gasket 80″. The number and arrangement of the gaskets 80 is exemplary, the platen 24b and clamp 68 can utilize more, or fewer, of the gaskets 80 to provide a fluid-tight seal for the chamber 50b.

The clamp 68 connects an upper edge portion 100 of the platen 24b to the lower edge portion 102 by extending horizontally over an overhang 104. The clamp 68 being connected to the upper edge portion 100 and the overhang 104 fixes the position of the outermost edge of the upper edge portion 100 to the overhang 104. In such an example, as fluid pressure in the chamber 50b changes, the clamp 68 maintains the relative position of the edge portions 100 and 102 such that the flexed region 60 is above the chamber 50b.

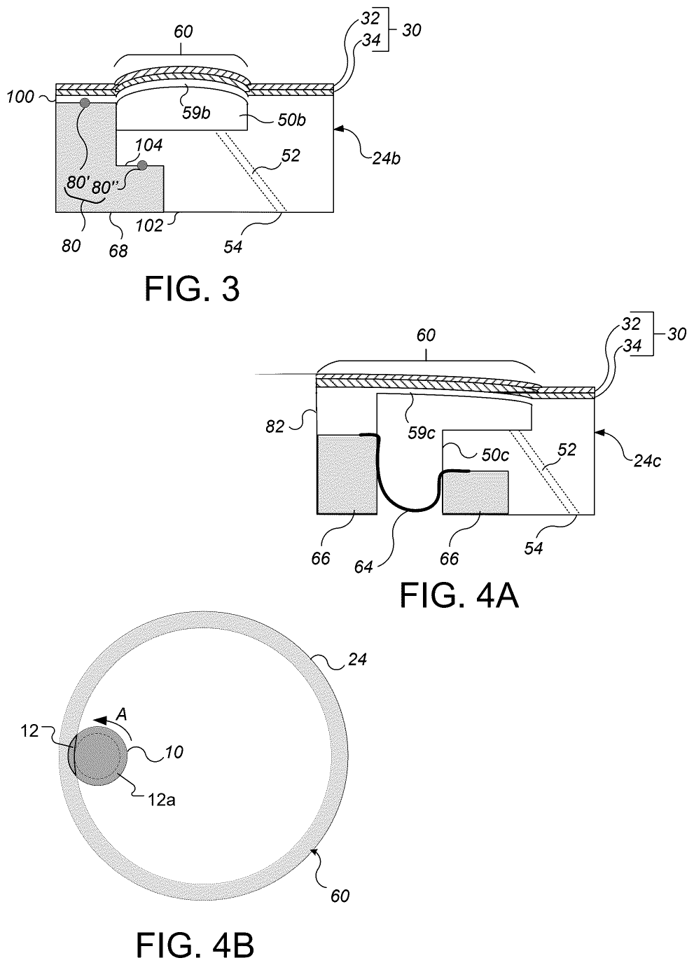

Other examples of the system 20 include chambers which generate polishing rate control zones at the edge of the platen 24. A platen 24c having an edge-control region 60 at the edge of the pad 30 is shown in FIG. 4A. A floor of the chamber 50c is sealed by clamps 66 which hold a flexure 64 to seal the floor of the annular chamber 50c. As the pressure in the chamber 50c increases, an outer edge 82 of the platen 24c is urged upward by the increasing pressure. The vertical distance the edge 82 is urged upward depends on the pressure within and dimensions of the chamber 50c and the flexibility of the plate 59c.

In the example platen 24c of FIG. 4A, the flexed region 60 is an annular region around the edge of the pad 30 as shown in FIG. 4B. As described herein, the substrate 10 is moved such that a portion 12 is above the flexed region 60. The flexed region 60 experiences increased or decreased pressure against the portion 12 depending on whether the region 60 is biased upward or downward and the annular section 12a of the substrate 10 experiences an increased or decreased polishing rate.

Examples of the system 20 includes a platen 24 having more than one chamber which results in increased numbers of profile control zones. A platen 24 having multiple chambers 50 can advantageously balance the over-or under-pressure within the chambers 50 to create profile control zones for performing edge-control during polishing of the substrate 10.

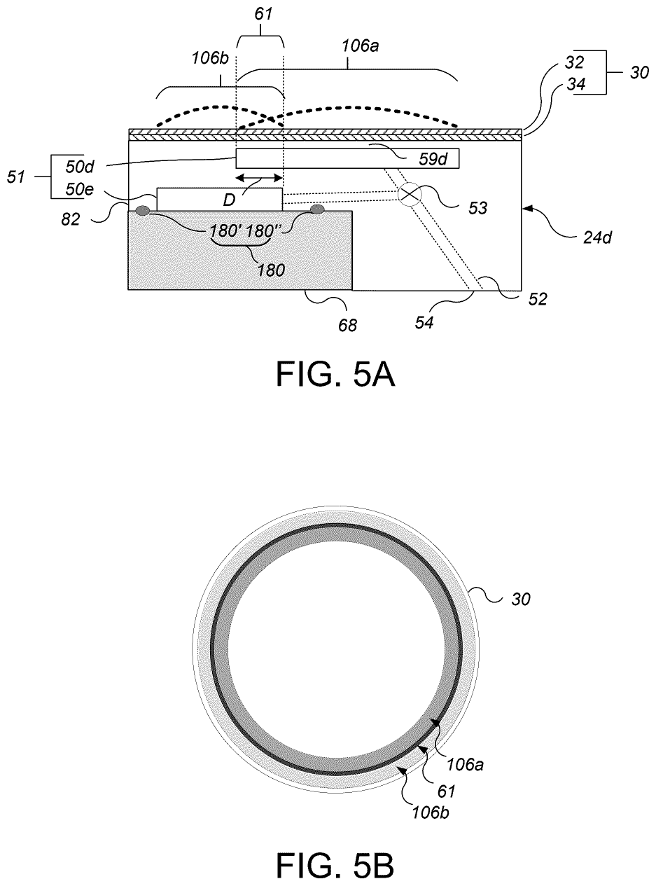

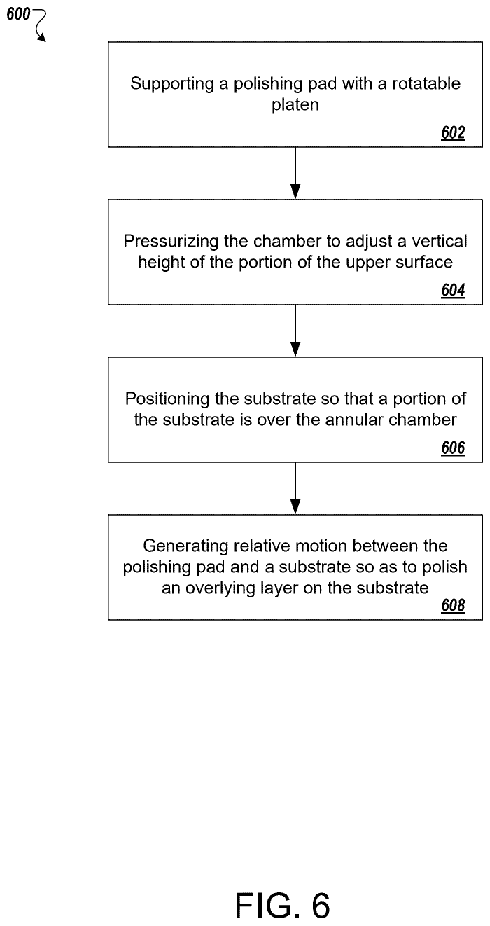

A platen 24d is shown in FIG. 5A having two chambers 51, e.g., an inner chamber 50d and an outer chamber 50e. In this case, the terms ‘outer’ and ‘inner’ refer to radial positions compared to the center of the platen 24d. ‘Outer’ refers to the chamber 50e being positioned radially further from the center, while ‘inner’ refers to the chamber 50d radially positioned nearer to the center. Each of the chambers 51 affects a region of the pad 30, e.g., inner chamber 50d displacing region 78a and region 78b outer chamber 50e displacing region 68b.

The inner chamber 50d includes a plate 59d between the chamber 50d and the pad 30. The plate 59d can be a unitary body with the platen 24d, e.g., such as plate 59, described above, or can be made from a different material than the platen 24d, such as ring 62 or cover 63.

The outer chamber 50e is sealed in the platen 24d by a clamp 68 and gaskets 180, including gasket 180′ and gasket 180″, which can be provided by the gaskets 80 described herein. As the clamp 68 is attached to the platen 24d at the outer edge 82, a pressure difference in the outer chamber 50e creates displacement in the outer edge 82 of the platen 24d thereby urging the pad 30 in region 78b upwards or downwards while a pressure difference in the inner chamber 50d urges the pad 30 in region 78a upwards or downwards.

The chambers 51 are independently, e.g., individually, pressurizable positioned at different vertical and horizontal positions within the platen 24d. In the example of FIG. 5A, the channel 52 is connected to a valve 53 which can direct fluid directed into the channel 52 to the chambers 51, either singularly, e.g., individually, or simultaneously, or terminate the flow of fluid altogether.

The radial widths of the chambers 51 overlap by a distance, D, thereby creating an overlapping region 61 of the pad 30 affected by the pressure in both chambers 51. In this manner, multi-region profile control can be achieved by controlling the pressures within the chambers 51. A top-view of the platen 24d and pad 30 is shown in FIG. 5B showing the regions 106a, 106b, and overlapping region 61.

Disclosed herein is a method 600 for polishing a region on a substrate by pressurizing a chamber in a platen. The polishing is accomplished using any substrate polishing system described herein, such as system 20.

A polishing pad is supported with a rotatable platen (step 602). The platen, e.g., one of platens 24 or 24a-d, comprising an annular chamber below and separated from a portion of an upper surface of the platen. The annular chamber can be separated from the upper surface by a disk-shaped cover, a ring, or a sheet of the platen.

The chamber is pressurized to adjust a vertical height of the portion of the upper surface relative to a central region along an entire circumference of the annular chamber (step 604). The system includes a pressure source in fluid connection with the annular chamber to provide a fluid to the chamber and change a fluid pressure within the chamber. Changing the fluid pressure within the chamber flexes, e.g., adjusts the vertical height, of the portion of the upper surface above the chamber. The portion of the upper surface flexes a portion of the polishing pad above the chamber up or down, depending on whether the fluid pressure within the chamber is increased or decreased.

The substrate is positioned so that an annular portion of the substrate is over the annular chamber (step 606). A controller of the system commands a carrier head restraining the substrate to position a portion of the substrate above the flexed portion of the polishing pad (e.g., flexed region 60).

Relative motion is generated between the polishing pad and the substrate so as to polish an overlying layer on the substrate (step 608). The controller commands a motor to rotate the carrier head such that the substrate beneath rotates. The relative motion causes the overlying layer to be polished, and the overlying layer in the portion of the substrate that is over the flexed portion of the pad is polished a differential rate than the remaining overlying layer according to presence and degree of flexing, determined by the fluid pressure in the annular chamber.

The method 600 can optionally include steps for determining a thickness profile of the overlying layer and controlling the polishing process to achieve a desired thickness profile using the system. In one embodiment, a thickness profile of the overlying layer is determined. The thickness profile can be determined using an in-situ monitoring system configured to communicate information about the thickness profile of the overlying layer to the controller.

Based on the thickness profile, the controller determines that an annular region, or a portion thereof, of the substrate requires differential polishing, (e.g., more polishing or less polishing that the portion of the substrate outside of the annular region). The controller commands the pressure source to change a pressure in the annular chamber thus adjusting the height of the portion of the upper surface of the platen relative to the central region to provide the differential polishing to at least a portion of the annular region of the substrate.

In one embodiment, the controller receives information from the in-situ monitoring system during the polishing process indicative of the thickness profile of the overlying layer. The controller stores a uniformity threshold for the thickness profile and compares the uniformity threshold to the thickness profile. In one example, the controller calculates a uniformity value based on the thickness profile to compare to the uniformity threshold. If the value is within the threshold, the controller determines to terminate differential polishing of the annular region of the substrate.

Here and throughout the specification, reference to a measurable value such as an amount, a temporal duration, and the like, the recitation of the value should be taken as disclosure of the precise value, of disclosure of approximately the value, and of disclosure of about the value, e.g., within ±10% of the value. For example, here reference to 100 microns can be taken as a reference to any of precisely 100 microns, approximately 100 microns, and within ±10% of 100 microns.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable subcombination.

What is claimed is:

1. A chemical mechanical polishing apparatus, comprising:
a platen having an upper surface to support a polishing pad, the platen having an annular chamber below and separated from a portion of an upper surface of the platen by a plate that is sufficiently flexible to deflect under a change of a pressure in the annular chamber, the platen having a channel fluidically connecting the annular chamber to a port in the platen;
a pressure source coupled to the port to control the pressure in the annular chamber;
a carrier head to hold a surface of a substrate against the polishing pad; and
a motor to generate relative motion between the platen and the carrier head so as to polish an overlying layer on the substrate.

2. The apparatus of claim 1, wherein the annular chamber has a radial width of up to 2 inches.

3. The apparatus of claim 1, wherein the plate comprises a ring secured over a recess in the platen to form the chamber.

4. The apparatus of claim 1, wherein the plate is a disk-shaped cover covering an entirety of the platen including over a recess to form the chamber.

5. The apparatus of claim 1, wherein the plate is a unitary body with a surrounding portion of the platen.

6. The apparatus of claim 1, wherein the plate is a metal material or polymer material.

7. The apparatus of claim 6, wherein the plate is aluminum having a thickness of up to 0.030 inches.

8. The apparatus of claim 6, wherein the plate is polyether ether ketone (PEEK) or polyphenylene sulfide (PPS) having a thickness of up to 0.080 inches.

9. The apparatus of claim 1, wherein a floor of the annular chamber is sealed with a flexure.

10. The apparatus of claim 9, wherein the flexure is affixed to the platen by an annular clamp.

11. The apparatus of claim 10, comprising an annular gasket between the clamp and the platen.

12. The apparatus of claim 10, wherein the annular clamp comprises a first clamp holding the flexure to an outer edge of the platen and a second clamp holding an opposing edge of the flexure to an inner portion of the platen.

13. The apparatus of claim 1, comprising a second annular chamber separated vertically from the annular chamber, the second annular chamber beneath a second portion of the upper surface of the platen, and the portion and the second portion are partially overlapping.

14. The apparatus of claim 13, wherein the second annular chamber is arranged at a different radial distance to a center of the platen than the annular chamber.

15. The apparatus of claim 13, wherein the second annular chamber is sealed with a second clamp.

16. The apparatus of claim 1, wherein the annular chamber comprises no more than an outermost 25% by radius of the platen.

17. A method of locally polishing a substrate, comprising:
supporting a polishing pad with a rotatable platen, the platen comprising an annular chamber below and separated from a portion of an upper surface of the platen;
pressurizing the chamber to adjust a vertical height of the portion of the upper surface relative to a central region along an entire circumference of the annular chamber;
positioning the substrate so that a portion of the substrate is over the annular chamber;
generating relative motion between the polishing pad and a substrate so as to polish an overlying layer on the substrate.

18. The method of claim 17, further comprising:
determining a thickness profile of the overlying layer;
determining, from the thickness profile, to provide differential polishing to an annular region of the substrate;
adjusting the height of the portion of the upper surface relative to the central region to provide the differential polishing to an annular region of the substrate.

19. The method of claim 17, further comprising continuing the relative motion between the polishing pad and the substrate until the region of the substrate is within a uniformity threshold of the remaining substrate.
